(19) United States
(12) Patent Application Publication
(10) Pub. No.: US 2025/0111426 A1
(43) Pub. Date: Apr. 3, 2025

(54) SYSTEM FOR TWO-DIMENSIONAL (2D) VIRTUAL CLOTHING FITTING USING A HYBRID DEEP LEARNING TECHNOLOGY INTEGRATING OPTIMIZATION AND DETERMINISTIC CLASSIFICATION ALGORITHMS

(71) Applicant: VIETTEL GROUP, Ha Noi City (VN)

(72) Inventors: QUANG TIEN PHAM, Nam Dinh City (VN); VAN DUC TRAN, Kien Xuong District (VN); HOANG VU NGUYEN, Vinh City (VN); TIEN DAT NGUYEN, Ha Noi City (VN); ANH TRA DUONG, Ha Noi City (VN)

(73) Assignee: VIETTEL GROUP, Ha Noi City (VN)

(21) Appl. No.: 18/899,906

(22) Filed: Sep. 27, 2024

(30) Foreign Application Priority Data
Oct. 3, 2023 (VN) 1-2023-06888

(51) Int. Cl. G06Q 30/0601; G06F 30/27

(52) U.S. Cl. CPC G06Q 30/0643; G06F 30/27

(57) ABSTRACT

The invention relates to a two-dimensional (2D) virtual clothing fitting system using machine learning technology and a deterministic classification algorithm. The system allows the construction of a two-dimensional (2D) digital interactive image between a cloth and the user's body instead of using a graphic engineer to simulate it. Machine learning models of image processing combined with a deterministic classification algorithm reproduce the user's image combined with the garment image and transform the cloth image according to the user's size.

### FIELD OF THE INVENTION

The invention relates to a system for two-dimensional (2D) virtual clothing fitting using a hybrid deep learning technology integrating optimization and deterministic classification algorithms. The proposed system could be applied in the fields of modeling and simulation.

### BACKGROUND

The system for virtual clothing fitting describes in detail the clothing interaction on users simulation using two-dimensional (2D) images of users combined with clothing images. In traditional, there are two types of system to reconstruct two-dimensional (2D) images of users on existing model images: (1) manual works of simulation graphics engineers, and (2) using basic machine learning models. Specifically, simulation graphics engineers perform editing, cropping, and correcting the user's head on existing model images, or vice versa, existing model images are directly grafted onto users' images and then edited by commercial software for lighting and background correction. In addition, some basic machine learning models directly graft the user's face onto the model image or vice versa, with the same steps as manual work, but at a lower level of accuracy and authenticity. An overview of the traditional system is presented in FIG. 1.

The disadvantages of the traditional system in the process of performing two-dimensional (2D) virtual fitting can be concluded into two parts: (1) the realism, which is affected by the position and size of the users' heads when performing direct stitching on the clothing image, and (2) the accuracy-traditional systems hardly describe accurately the users' size on clothing images. Simulation graphics engineers can handle each individual case, but the labor cost and implementation time are extremely huge and cannot be expanded and applied on an industrial scale.

### SUMMARY OF THE INVENTION

The purpose of the invention is to propose a virtual clothing fitting system using machine learning technology and optimization algorithms. Machine learning models on image processing are combined with optimization algorithms and classification algorithms to reconstruct user images combined with clothing images and transform clothing images according to the user's size. This processing and output generation consists of two main parts: first is to use optimization algorithms and human body parameter models to build the user's size, thereby transforming the shape and size of the two-dimensional (2D) clothing image, and second is to use machine learning models to change and calibrate the user's head with the two-dimensional (2D) clothing image.

To achieve the above purpose, the virtual clothing fitting system uses machine learning technology combining optimization and deterministic classification algorithms, which includes four main blocks: data preprocessing block, shape modification block, swapping block, and calibration and optimization block.

The data preprocessing block consists of five modules: segmentation module, mid-neck axis determination module, facial and body landmark determination module, model coefficient determination module, user face classification module.

The shape modification block consists of three modules: a three-dimensional (3D) human data estimation module, a two-dimensional (2D) mesh surface generation module, a two-dimensional (2D) image extraction module used to determine the user size, determine the updated neck center axis coefficient, update clothing image segmentation, and change the shape of the two-dimensional (2D) clothing image corresponding to the user size.

The swapping block consists of six modules: user neck-and-face segmentation module, user facial landmark detection module, user occluded neck reconstruction module, skin color change module, user face classification module, and image swapping module. This block uses machine learning models and optimization algorithms to perform the swapping of two-dimensional (2D) clothing model images and updated user images.

The calibration and optimization block consists of five modules: user head size calculation module, user and model face type comparison module, user head position calculation module, user head position and size adjustment module, and seamless skin color processing module.

### BRIEF DESCRIPTION OF THE DRAWINGS

FIG. 1 is a traditional system diagram representation;

FIG. 2 is a schematic diagram of the virtual clothing try-on system mentioned in the invention;

FIG. 3 depicts the context of data collection;

FIG. 4 illustrates the data preprocessing block;

FIG. 5 is a drawing depicting nine facial landmarks located relative to the jawbone;

FIG. 6 is a detailed description of the shape modification block;

FIG. 7 is a drawing depicting details of the swapping block; and

FIG. 8 describes the calibration and optimization block.

### DETAILED DESCRIPTION OF THE INVENTION

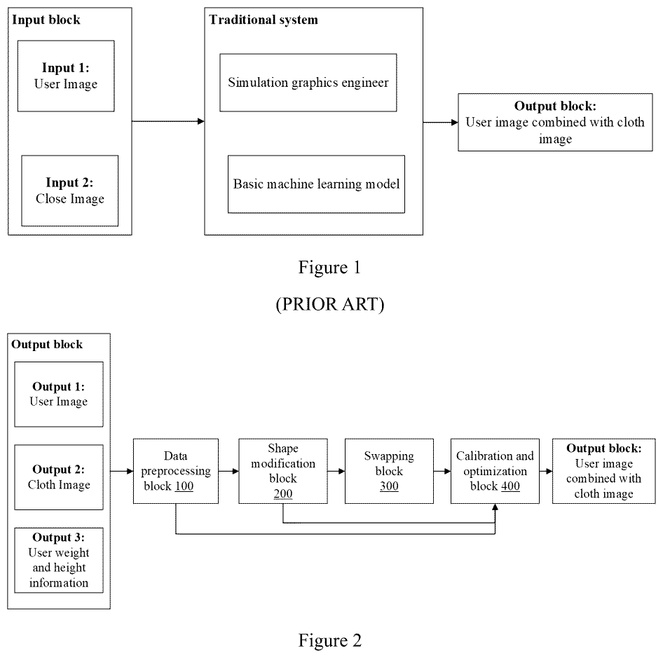

As shown in FIG. 1 and FIG. 2, the invention introduces a new system for reconstructing the user's fitting images on corresponding model clothes using machine learning technology integrating optimization and deterministic classification algorithms, instead of using simulation graphics engineers and basic machine learning models. The application of the system will solve two main problems currently encountered, namely the realism and accuracy of the model output.

In this invention, the following terms are construed as follows:

“Joints” in the human body are the points, or rather surfaces, where bones physically connect to each other.

“Joints” in clothing, similar to joints in the human body, are the connections between the predetermined joints of the clothing.

“Person/clothing landmarks” (key points) are characteristic points on a photograph of a person/clothing. Landmarks are typical points lying on boundaries and are meaningful in the identification, segmentation, or referencing process for a particular problem.

“Person/clothing boundaries” are concepts related to clothing boundaries in an image. Clothing boundaries are crucial in the extraction and segmentation process of defining different data regions from an image.

“A model image” is a photo or a set of photos capturing a costume according to predetermined standards such as a front photo, a photo of the front of the costume worn by the model, in which the model looks straight and poses with the costume.

“A UV map” stores parameters for projecting a two-dimensional (2D) image onto a three-dimensional (3D) model surface.

As shown in FIG. 2, the virtual try-on system utilizes machine learning models and optimization algorithms that are different from traditional systems. Specifically, the system includes four main blocks: data preprocessing block 100, shape modification block 200, swapping block 300, and calibration and optimization block 400. In addition, there are input blocks and output blocks.

The input block includes three main parts: user image, clothing image, and user height and weight information. The data goes through data preprocessing block 100 for correction, preprocessing to retrieve necessary information from users and models for use in shape modification block 200, and calibration and optimization block 400. The shape modification block 200 transforms the model image according to the user's size. The output of this block is the input to the swapping block 300 and the calibration and optimization block 400, where the swapping block 300 plays a role in combining the updated user image and the updated model image. The output of block 300 continues to be passed through the calibration and optimization block 400 to post-process the results of matching the user's head and model, helping to achieve naturalness and authenticity in the results. The output of the block, which is also the system output, is the user image combined with the clothing image.

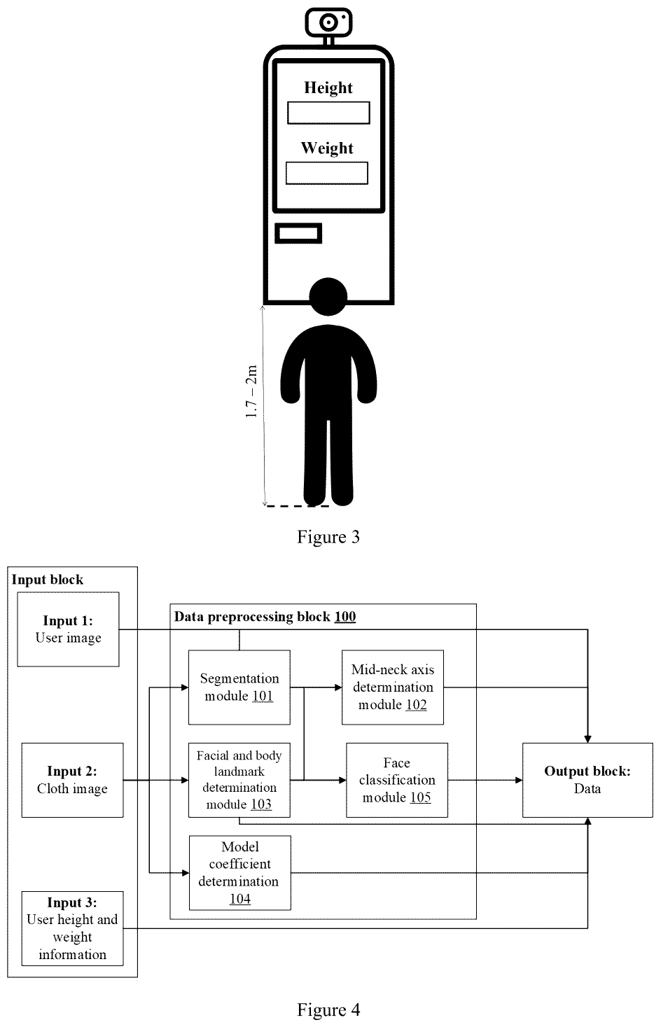

According to FIG. 3, the input block collects data using a computer device with a screen and a camera. The user enters the height and weight into the device, and then a photo of the user is taken using a camera mounted on top of the device at 1.7-2 m from the user to the device. The clothing image data is collected from the device's internal memory.

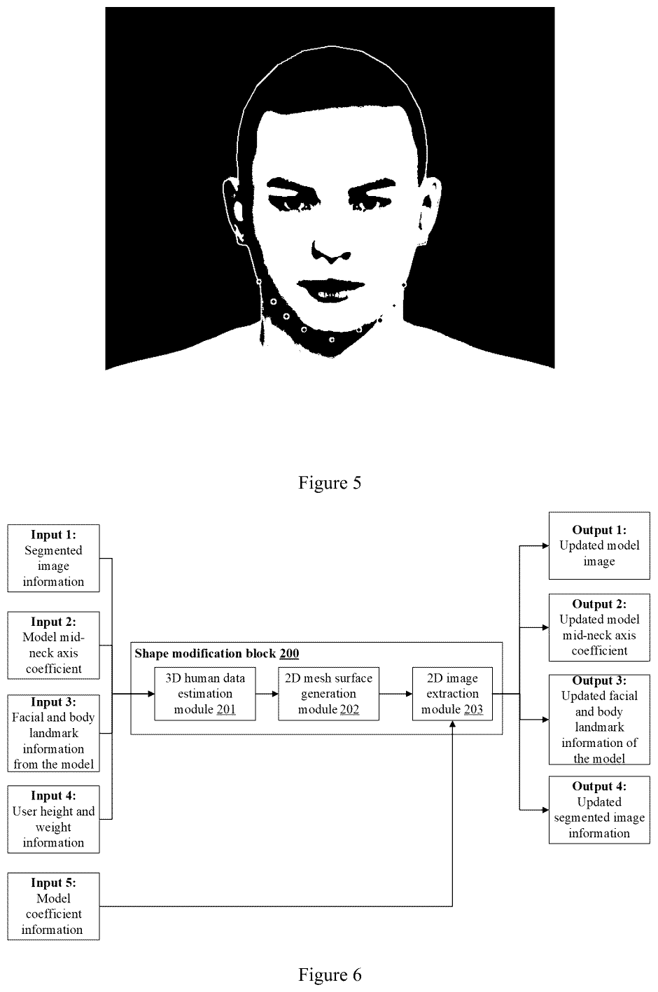

Reference FIG. 4, the input data in the data preprocessing block 100 consists of three parts mentioned in the input block: user image, clothing image, and user height and weight information. The five modules in the data preprocessing block 100 include segmentation module 101, mid-neck axis determination module 102, facial and body landmark determination module 103, model coefficient determination module 104, and face classification module 105. The segmentation module 101 uses a machine learning model to identify the boundary between the clothing and the model with the surrounding background, using the clothing image as input. The facial and body landmark determination module 103 employs a machine learning model to identify and classify facial and body landmarks based on the clothing image. The outputs of modules 101 and 103 combined with the clothing image are the input for the mid-neck axis determination module 102. From the landmarks obtained by module 103, nine points correlated with the jawbone are selected (reference FIG. 5), and the jawline is a line drawn between these points. The jawline is extended by the following formula:

$${jawline}_{ext} ( x , y ) = max ( jawline ( x - i , y - j ) \vert S ( i , j ) )$$

In which:
(x,y) represents the pixel coordinates on the image depicting the jawline;
(i,j) represents the pixel coordinates on the structural element S, where the size of the structural element S is proportional to the pupillary distance estimated from the facial landmarks obtained from module 103;
jawlineₑₓₜ(x,y) is the pixel value after extension at coordinates (x,y);
S(i,j) is the pixel value of the structural element at coordinates (i,j).
max( ) is the operator used to find the maximum value among the correlated pixels between the image representing the jawline and the structural element.

The chin area is defined as the intersection between the extended jawline and the segmented neck region obtained from the segmentation module 101 and is represented by the following formula:

$${chin}_{mask} = {jawline}_{ext} ( x , y ) {∩neck}_{mask}$$

With chinₘₐₛₖ and neckₘₐₛₖ representing the chin area and the segmented neck region, respectively. It is assumed that on chinₘₐₛₖ, the pixels with a value of 1 indicate that they are within the chin area, while pixels with a value of 0 indicate that they are outside the chin area. The mid-neck axis is represented by the following equation:

$$\begin{matrix}x = \frac{( {x}_{min} + {x}_{max} )}{2} \\ {x}_{min} = min ( x ) ∀ ( x , y ) \vert {chin}_{mask} ( x , y ) = 1 \\ {x}_{max} = max ( x ) ∀ ( x , y ) \vert {chin}_{mask} ( x , y ) = 1\end{matrix}$$

In which:
xₘᵢₙ and xₘₐₓ are the minimum and maximum values along the x-axis of the chin area chinₘₐₛₖ, respectively.

The model coefficient determination module 104 uses a nonlinear optimization algorithm to determine the model parameters in the image. These parameters are utilized as a reference base for input to the shape modification block 200. The model parameters are characterized by the pose and shape parameters of the parametric human model and the virtual camera parameters used to project the parametric human model onto a two-dimensional (2D) image. These parameters are initially rough estimates and are continuously refined through the Adam optimization algorithm to find solutions that minimize the following objective function:

$$E = {ω}_{J} . {E}_{J} ( θ , β , K , {J}_{e} ) + {ω}_{weight} . {E}_{weight} + {ω}_{height} . {E}_{height} + {ω}_{β} . {E}_{β}$$

In which:
E_{J}=Σᵢωᵢρ(J_{M}−Jₑ): joint position error on the two-dimensional (2D) image;
E_{weight}=∥pd_weight−gt_weight∥: weight error;
E_{height}=∥pd_height−gt_height∥: height error;
E_{β}^{m}=β^{T}Σ_{β}⁻¹β: shape error;
M: parametric human model.
ω_{J}, ω_{weight}, ω_{height}, ω_{β}: real-valued parameters;
θ, β: the pose and shape parameters of the parametric model M;
K: camera's parameters;
J_{M}: projected positions of the three-dimensional (3D) joints of the parametric model M onto the image;
Jₑ: denotes the positions of the two-dimensional (2D) joints of the real person on the image; ρ denotes the Geman-McClure function.

The face classification module 105 uses input from the segmentation module 101 and the facial and body landmark determination module 103 to calculate parameters such as forehead width (d_{forehead}), cheekbone width (d_{cheekbone}), chin width (d_{chin}), and face length (d_{face}). By comparing these parameter values, the face shape of the individual being examined can be concluded. The face shapes considered are oval, long rectangular, and round, and are specifically defined as follows:
Oval face: (d_{face}>d_{cheekbone})&(d_{forehead}>d_{chin});
Long rectangular face: d_{face}>d_{cheekbone}≈d_{forehead}≈d_{chin};
Round face: d_{cheekbone}≈d_{face}>d_{forehead}≈d_{chin};

The output from the data preprocessing block 100 is used in the head pose updating block 200 and the calibration and optimization block 400.

Reference FIG. 6, the input data in the shape modification block 200 consists of five parts: segmented image information, model mid-neck axis coefficient, facial and body landmark information from the model, model coefficient information from the output of the data preprocessing block 100, and user height and weight information from the input block. The shape modification block 200 includes three main modules: the three-dimensional (3D) human data estimation module 201, the two-dimensional (2D) mesh surface generation module 202, the two-dimensional (2D) image extraction module 203. Specifically, the three-dimensional (3D) human data estimation module 201 uses an optimization algorithm to determine the three-dimensional (3D) human mesh model based on height and weight information, with an objective function similar to the model coefficient determination module 103 but only utilizing three objective functions E_{weight}, E_{height}, E_{β}. The two-dimensional (2D) mesh surface generation module 202 uses the model coefficient information to generate a three-dimensional (3D) mesh model and applies perspective projection to project the three-dimensional (3D) mesh into two-dimensional (2D) points that match the model shape in the image. Then, a triangular mesh for the obtained two-dimensional (2D) points, generated by the Delaunay triangulation algorithm, is normalized to the range [0, 1] to create a UV map, and the model image is attached as texture to the two-dimensional (2D) mesh model. The two-dimensional (2D) image extraction module 203 uses perspective projection to project the three-dimensional (3D) human mesh model obtained in the three-dimensional (3D) human data estimation module 301 into two-dimensional (2D) points. To transform the body shape in the two-dimensional (2D) image, it is necessary to calculate the transformation matrix for each pixel on the image. This process is carried out in two steps: first, the transformation matrix of the projected points from the three-dimensional (3D) human model is calculated, and second, the matrix for all pixels is interpolated. The transformation matrix between the projected points of the model and the user is calculated through an optimization algorithm using the following objective function:

$${E}_{A} = {ω}_{p} {E}_{p} ( {J}_{m} , {J}_{u} ) + {ω}_{e} {E}_{e}$$

In which:
ωₚ, ωₑ: real-valued parameters;
Eₚ(Jₘ,Jᵤ)=∥ₘ−Jᵤ∥₂: pixel position error;
Jₘ,Jᵤ: two-dimensional (2D) position of the projection points of the model and user;
Eₑ=ΣᵢΣⱼ∥Aᵢ−Aⱼ: The error that ensures the preservation of the image structure.
Aᵢ, Aⱼ are the transformation matrices of pixels i and j, which belong to the same edge of a triangle on the two-dimensional (2D) mesh model generated by the two-dimensional (2D) mesh surface generation module 202;

The matrix for all pixels is interpolated from the transformation matrices of the projected points of the human model as follows:

$${A}_{k} = \frac{1}{n} {\sum }_{l} {A}_{l}$$

Aₖ: the transformation matrix of pixel k;
Aₗ: the transformation matrix of a neighboring pixel l to pixel k on the projected points of the human model.

The output of the shape modification block 200 includes the updated model image, updated model mid-neck axis coefficient, updated facial and body landmark information of the model, and updated segmented image information, which is used as input for the swapping block 300 and the calibration and optimization block 400.

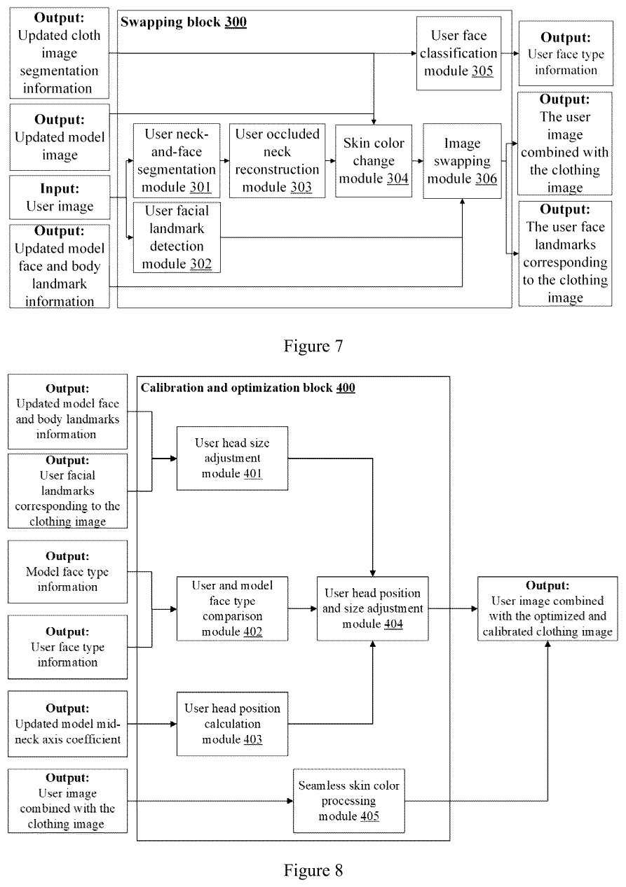

As shown in FIG. 7, the input data of the swapping block 300 consists of four parts: the updated cloth image segmentation information and the updated cloth image from the shape change block 200, the user image from the input block, and the updated model face and body landmark information from the shape change block 200. The swapping block 300 consists of six modules: user neck-and-face segmentation module 301, user facial landmark detection module 302, user occluded neck reconstruction module 303, skin color change module 304, user face classification module 305, and image swapping module 306. The user neck-and-face segmentation module 301 uses a deep learning network to divide the portrait image into eighteen segments (skin, nose, eyeglasses, left eye, right eye, left eyebrow, right eyebrow, left ear, right ear, mouth, upper lip, lower lip, hair, hat, earrings, necklace, neck, and clothing) thereby removing unnecessary parts (including background region (region not included in the above eighteen regions), clothing, necklace). The user facial landmark detection module 302 uses a deep learning network to extract sixty-eight two-dimensional (2D) coordinates of key points on the user face image. With the user face and neck segmentation module 301 output, the user occluded neck reconstruction module 303 uses a generative adversarial network (GAN) model to automatically identify and restore the user neck region occluded by clothing. A generative adversarial network (GAN) is defined by each probability space (Ω, μ_{ref}) and consists of two main parts: a generator and a discriminator. The generator uses P(Ω) as the set of all measurement probabilities μ_{G} on Ω; the discriminator uses a Markov kernel μ_{D}: Ω→P[0,1], where P[0,1] is the set of measurement probabilities on [0,1]. The objective function of a GAN is expressed by the formula (extracted from the paper Generative Adversarial Nets by Ian J. Goodfellow):

$$L ( {μ}_{G} , {μ}_{G} ) := {E}_{x ∼ {μ}_{ref} , y ∼ {μ}_{D} ( x )} [ ln y ] + {E}_{x ∼ {μ}_{G} , y ∼ {μ}_{D} ( x )} [ ln ( 1 - y ) ]$$

In the objective function, the generator minimizes the value, and the discriminator maximizes the value. The correlation between the two makes the GAN model can be considered as a zero-sum game.

The skin color change module 304 uses a K-means clustering algorithm to segment the skin color of the user and the model, thereby changing the skin color of the model to the user's skin color by adjusting the luminance curve for each color channel in the image. The user face classification module 305 classifies the user's face in a similar way to module 105 used in the data preprocessing block 100. The image swapping module 306 calculates a transformation matrix M from the key points obtained in the facial landmark detection module 302 and uses an image distortion algorithm to transform the user's face image to match the model's face. The matrix M is calculated based on the following spatial matrix transformations:

$$M = [ \begin{matrix}scale . R & {c}_{u}^{T} - scale . R . {c}_{m}^{T} \\ 0 & 1\end{matrix} ]$$

$$R = {( U . {( V )}^{T} )}^{T}$$

$$U , \sum , {( V )}^{T} = SVD ( {( {lmk}_{m} )}^{T} . {lmk}_{u} )$$

$${c}_{u} = mean ( {lmk}_{u} ) , {c}_{m} = mean ( {lmk}_{m} )$$

$$‖ {lmk}_{m} ‖ = \frac{{lmk}_{m} - {c}_{m}}{std ( {lmk}_{m} - {c}_{m} )} ; ‖ {lmk}_{u} ‖ = \frac{{lmk}_{u} - {c}_{u}}{std ( {lmk}_{u} - {c}_{u} )}$$

$$scale = \frac{std ( {lmk}_{u} - {c}_{u} )}{std ( {lmk}_{m} - {c}_{m} )}$$

Where: lmkₘ, lmkᵤ are the landmarks identified on the model and user's faces; mean: calculates the average value of the dataset; std: measures the dispersion of the dataset around the mean value; SVD: decomposition of a matrix into the product of orthogonal matrices and non-square diagonal matrices.

The swapping block 300 output is the user face type information, the user image combined with the clothing image, and the user face landmarks corresponding to the clothing image.

Referring to FIG. 8, the input data of the calibration and optimization block 400 includes the updated model face and body landmarks information from block 200, the user facial landmarks corresponding to the clothing image from block 300, the model face type information from block 100, the user face type information from block 300, the updated model mid-neck axis coefficient from block 200, and the user image combined with the clothing image from block 300. In the calibration and optimization block 400, the user head size adjustment module 401 uses the user and model landmarks to adjust the appropriate head ratio. The head ratio is calculated for different cases as follows:

### For Male:

### Full Body Photo:

scale_{head}=scale_{chin}

### Half Body Photo:

$${scale}_{head} = ( {scale}_{eye} + {scale}_{chin} * 3 ) / 4$$

### For Female:

$${scale}_{head} = ( {scale}_{eye} + {scale}_{chin} ) / 2$$

There, scale_{head} is the head ratio to be adjusted, and scale_{eye} and scale_{chin} are the eye and chin ratios between the user and the model image, respectively, calculated based on the two sets of corresponding landmarks of the user and the model image. The user head position calculation module 403 adjusts the user head position to the center of the neck of the model image along the horizontal axis of the image. The user and model face type comparison module 402 compares the face type information between the user and the model to add information about the appropriate head ratio and position. The user head position and size adjustment module 404 receives information from the user head position and size update modules 401, 402, and 403 to calculate a new transformation matrix M similar to the image swapping module 306 in the image swapping block 300. The seamless skin color processing module 405 uses the Poisson equation combined with the Dirichlet boundary condition. The gradient field value in the composite image region is calculated and adjusted to match the user image, minimizing the color difference in the contiguous skin region between the user and the clothing image. The calibration and optimization block 400 output is the user image combined with the optimized and calibrated clothing image.

What is claimed is:

1. A system for two-dimensional (2D) virtual clothing fitting using a hybrid deep learning technology integrating optimization and deterministic classification algorithms, including:
a data preprocessing block uses image processing techniques and machine learning models to process, normalize, and standardize input images, and identify and segment regions on user images and two-dimensional (2D) clothing images, including:
a segmentation module,
a mid-neck axis determination module,
a facial and body landmark determination module,
a model coefficient determination module,
and a face classification module,
the segmentation module uses a machine learning model to identify the boundary between the clothing images and a model with a surrounding background, using the clothing image as input; the facial and body landmark determination module employs a machine learning model to identify and classify facial and body landmarks based on the clothing image; the outputs of the segmentation and facial and body landmark determination modules combined with the clothing image are the input for the mid-neck axis determination module; from the landmarks obtained by the facial and body landmark determination module, nine points correlated with a jawbone are selected, and a jawline is a line drawn between these points; the jawline is extended by the following formula:
$${jawline}_{ext} ( x , y ) = max ( jawline ( x - i , y - j ) / S ( i , j ) )$$
in which:
(x,y) represents the pixel coordinates on the image depicting the jawline;
(i,j) represents the pixel coordinates on the structural element S, where the size of the structural element S is proportional to a pupillary distance estimated from the facial landmarks obtained from the facial and body landmark determination module;
jawlineₑₓₜ(x,y) is the pixel value after extension at coordinates (x,y);
S(i,j) is the pixel value of the structural element at coordinates (i,j);
max( ) is the operator used to find the maximum value among the correlated pixels between the image representing the jawline and the structural element;
the chin area is defined as the intersection between the extended jawline and the segmented neck region obtained from the segmentation module and is represented by the following formula:
$${chin}_{mask} = {jawline}_{ext} ( x , y ) {∩neck}_{mask}$$
with chinₘₐₛₖ and neckₘₐₛₖ representing the chin area and the segmented neck region, respectively; it is assumed that on chinₘₐₛₖ, the pixels with a value of 1 indicate that they are within the chin area, while pixels with a value of 0 indicate that they are outside the chin are; the mid-neck axis is represented by the following equation:
$$\begin{matrix}x = \frac{( {x}_{min} + {x}_{max} )}{2} \\ {x}_{min} = min ( x ) ∀ ( x , y ) \vert {chin}_{mask} ( x , y ) = 1 \\ {x}_{max} = max ( x ) ∀ ( x , y ) \vert {chin}_{mask} ( x , y ) = 1\end{matrix}$$
in which:
xₘᵢₙ and xₘₐₓ are the minimum and maximum values along the x-axis of the chin area chinₘₐₛₖ, respectively;
the face classification module uses input from the segmentation module and the facial and body landmark determination module to calculate parameters such as forehead width (d_{forehead}), cheekbone width (d_{cheekbone}), chin width (d_{chin}), and face length (d_{face}), by comparing these parameter values, the face shape of the individual being examined can be concluded; the face shapes considered are oval, long rectangular, and round, and are specifically defined as follows:
oval face: (d_{face}>d_{cheekbones})&(d_{forehead}>d_{chin});
long rectangular face: d_{face}>d_{cheekbone}≈d_{forehead}≈d_{chin};
round face: d_{cheekbone}≈d_{face}>d_{forehead}≈d_{chin};
the shape modification block includes three main modules:
a three-dimensional (3D) human data estimation module uses an optimization algorithm to determine the three-dimensional (3D) human mesh model based on height and weight information, with an objective function similar to the model coefficient determination module 103 but only utilizing three objective functions E_{weight}, E_{height}, E_{β};
a two-dimensional (2D) mesh surface generation module uses the model coefficient information to generate a three-dimensional (3D) mesh model and applies perspective projection to project the three-dimensional (3D) mesh into two-dimensional (2D) points that match the model shape in the image; then, a triangular mesh for the obtained two-dimensional (2D) points, generated by the Delaunay triangulation algorithm, is normalized to the range [0, 1] to create a UV map, and the model image is attached as texture to the two-dimensional (2D) mesh model;
a two-dimensional (2D) image extraction module uses perspective projection to project the three-dimensional (3D) human mesh model obtained in the three-dimensional (3D) human data estimation module 301 into two-dimensional (2D) points;
a swapping block consists of six modules:
a user neck-and-face segmentation module,
a user facial landmark detection module,
a user occluded neck reconstruction module,
a skin color change module,
a user face classification module,
an image swapping module,
the user neck-and-face segmentation module uses a deep learning network to divide the portrait image into eighteen segments (skin, nose, eyeglasses, left eye, right eye, left eyebrow, right eyebrow, left ear, right ear, mouth, upper lip, lower lip, hair, hat, earrings, necklace, neck, and clothing) thereby removing unnecessary parts; the user facial landmark detection module uses a deep learning network to extract sixty-eight two-dimensional (2D) coordinates of key points on the user face image, with the user face and neck segmentation module output, the user occluded neck reconstruction module uses a generative adversarial network (GAN) model to automatically identify and restore the user neck region occluded by clothing, a generative adversarial network (GAN) is defined by each probability space (Ω, μ_{ref}) and consists of two main parts: a generator and a discriminator, the generator uses P(Ω) as the set of all measurement probabilities μ_{G} on Ω; the discriminator uses a Markov kernel μ_{D}: Ω→P[0,1], where P[0,1] is the set of measurement probabilities on [0,1], the objective function of a GAN is expressed by the formula:
$$L ( {μ}_{G} , {μ}_{G} ) := {E}_{x ∼ {μ}_{ref} , y ∼ {μ}_{D} ( x )} [ ln y ] + {E}_{x ∼ {μ}_{G} , y ∼ {μ}_{D} ( x )} [ ln ( 1 - y ) ]$$
a calibration and optimization block includes five modules:
a user head size adjustment module uses the user and model landmarks to adjust the appropriate head ratio; the head ratio is calculated for different cases as follows:
for male:
full body photo:
scale_{head}=scale_{chin}
half body photo:
$${scale}_{head} = ( {scale}_{eye} + {scale}_{chin} * 3 ) / 4$$
for female:
$${scale}_{head} = ( {scale}_{eye} + {scale}_{chin} ) / 2$$
there, scale_{head} is the head ratio to be adjusted, and scale_{eye} and scale_{chin} are the eye and chin ratios between the user and the cloth image, respectively, calculated based on the two sets of corresponding landmarks of the user and the cloth image;
a user head position calculation module adjusts the user head position to the center of the neck of the model image along the horizontal axis of the image;
a user and model face type comparison module compares the face type information between the user and the model to add information about the appropriate head ratio and position;
a user head position and size adjustment module receives information from the user head size adjustment module, the user and model face type comparison module, and the user head position calculation module to calculate a new transformation matrix M similar to the image swapping module in the image swapping block;
a seamless skin color processing module uses the Poisson equation combined with the Dirichlet boundary condition; the gradient field value in the composite image region is calculated and adjusted to match the user image, minimizing the color difference in the contiguous skin region between the user and the cloth image.
